(19) United States
(12) Patent Application Publication
(10) Pub. No.: US 2014/0172340 A1
(43) Pub. Date: Jun. 19, 2014

(54) DEBUGGING METHOD FOR PRE-ALIGNMENT

(71) Applicant: PEKING UNIVERSITY FOUNDER GROUP CO., LTD., Beijing (CN)

(72) Inventor: Ruiteng YIN, Shenzhen (CN)

(73) Assignee: PEKING UNIVERSITY FOUNDER GROUP CO., LTD., Beijing (CN)

(21) Appl. No.: 14/091,873

(22) Filed: Nov. 27, 2013

(30) Foreign Application Priority Data
Dec. 14, 2012 (CN) 201210546702.0

(51) Int. Cl. H01L 21/66

(52) U.S. Cl. CPC H01L 22/20
USPC 702/84

(57) ABSTRACT

The application discloses a debugging method for pre-alignment applicable to an electronic device and the method includes: obtaining a preset voltage value which is an average voltage value of a first voltage value corresponding to a thin wafer placed on a table of the electronic device and a second voltage value corresponding to a thick wafer placed on the table of the electronic device; detecting and acquiring a first operation, and correcting a third voltage value of the electronic device according to the preset voltage value in response to the first operation so that a voltage difference between the third voltage value and the preset voltage value lies in a preset voltage range; detecting location of a flatten edge of the thick wafer on the table of the electronic device to obtain first location information, and detecting location of a flatten edge of the thin wafer on the table of the electronic device to obtain second location information; and detecting and acquiring a second operation, and correcting the second location information according to the first location information in response to the second operation so that an angle difference between the corrected second location information and the first location information lies in a preset angle range.

### CROSS REFERENCE TO RELATED APPLICATIONS

This application claims priority to Chinese Application Number 201210546702.0, filed on Dec. 14, 2012, the entirety of which is incorporated herein by reference.

### FIELD OF THE INVENTION

The present application relates to the field of semiconductor manufacturing devices and particularly to a debugging method for pre-alignment.

### BACKGROUND OF THE INVENTION

A large number of semiconductor products have been produced along with an increasingly extended scope in which semiconductors are applied. A high precision of a photo-lithography machine is required in a process of pre-aligning a silicon wafer during photo-lithographing steps of manufacturing a semiconductor.

The process of pre-aligning the silicon wafer is performed when the silicon wafer is loaded so as to determine a flatten edge of the silicon wafer (the location where the silicon wafer is cut), and when the silicon wafer is rotated at a low speed, light of a light emitting diode at the flatten edge can pass, and a change in intensity of the light is detected by a sensor opposite thereto, so that the center and the flatten edge of the silicon wafer can be determined after photo-electric conversion. A photo-lithography process has alignment marks left on the silicon wafer for positioning at subsequent levels. Starting from a second photo-lithography process, alignment at the respective levels is performed by determining coordinates through moving the silicon wafer relative to reference marks according to the coordinates of the alignment marks at the preceding levels defined in a mask file. However the inventors of the application have found during making of a technical solution in embodiments of the application at least the following technical problem in the above-mentioned technology:

In the prior art, a hardware positioning system of a pre-aligning device in the photo-lithography machine is unchanged, and there are various specifications of silicon wafer products to be produced, such as thin wafers and thick wafers, where there are an approximately difference of 100,000 μm between thin and thick wafers in terms of distances between flatten edges and a difference of 2,000 μm between them in terms of diameters of the flatten edges, so there are different requirements on the positioning system in the pre-aligning process of the thick and thin wafers, so that the thin wafer product has to be operated on a single machine, search marks have to be imprinted with the aid of human intervention, and the positioning system for the thick wafer can not be reused, thus resulting in such a technical problem that the thin and thick wafers can not be operated compatibly.

### SUMMARY OF THE INVENTION

Embodiments of the application provide a debugging method for pre-alignment so as to address the technical problem in the prior art that thin and thick wafers can not be operated on the same exposure machine.

An embodiment of the application provides a debugging method for pre-alignment, which includes:

obtaining a preset voltage value which is an average voltage value of a first voltage value corresponding to a thin wafer placed on a table of the electronic device and a second voltage value corresponding to a thick wafer placed on the table of the electronic device;

detecting and acquiring a first operation, and correcting a third voltage value of the electronic device according to the preset voltage value in response to the first operation so that a voltage difference between the third voltage value and the preset voltage value lies in a preset voltage range;

detecting location of a flatten edge of the thick wafer on the table of the electronic device to obtain first location information, and detecting location of a flatten edge of the thin wafer on the table of the electronic device to obtain second location information; and

detecting and acquiring a second operation, and correcting the second location information according to the first location information in response to the second operation so that an angle difference between the corrected second location information and the first location information lies in a preset angle range.

Optionally, after detecting and acquiring the second operation and correcting the second location information according to the first location information in response to the second operation, the method further includes:

detecting and acquiring a third operation, and generating a first instruction in response to the third operation to extend a stroke of the table of the electronic device in a Y direction, wherein the third operation is an operation to remove a cylinder stroke baffle of the table of the electronic device in the Y direction.

Optionally, after detecting and acquiring the third operation and generating the first instruction in response to the third operation to extend the stroke of the table of the electronic device in the Y direction, the method further includes:

detecting and acquiring a fourth operation, and generating a second instruction in response to the fourth operation to have pre-aligned centers of the thin and thick wafers controlled within a preset length range, wherein the fourth operation is an operation to adjust a distance between preset wheels of the table of the electronic device in the Y direction.

Optionally, after detecting and acquiring the fourth operation and generating the second instruction in response to the fourth operation to have the pre-aligned centers of the thin and thick wafers controlled within the preset length range, the method further includes:

detecting and acquiring a fifth operation when there is a silicon wafer required to be processed into the thick or thin wafer and the silicon wafer is placed on the table of the electronic device, and generating a third instruction in response to the fifth operation to fix the silicon wafer, wherein the fifth operation is an operation to fix the silicon wafer respectively in three directions Y, X and T of the table of the electronic device.

Optionally, after detecting and acquiring the fifth operation and generating the third instruction in response to the fifth operation to fix the silicon wafer, the method further includes:

detecting thin and thick wafers placed on the table of the electronic device respectively;

obtaining a preset number of detection results; and

correcting software parameters of the electronic device according to the detection results.

One or more technical solutions according to the embodiments of the application have at least the following technical effects or advantages:

(1) In the embodiments of the application, the voltage value of the machine is adjusted according to the average value of the voltages of the thick and thin wafers separately operated on the machine so that the voltage value of the machine can accommodate both the thick and thin wafers for operation, and the location of the flatten edge of the thin wafer on the machine is adjusted according to the location of the flatten edge of the thick wafer on the machine so that the positioning system of the machine can position both the flatten edges of the thick and thin wafers, thereby addressing the technical problem in the prior art that the thin wafer can not be operated on the machine with which the thick wafer is manufactured and achieving the technical effect of operating the thick and thin wafers compatibly.

(2) In the embodiments of the application, the voltage values required for the exposure machine in manufacturing the finished thick and thin wafers are detected and then averaged, and the voltage value of the exposure machine is adjusted using the average voltage value, thereby addressing the technical problem in the prior art that voltage test points of the exposure machine can only be directly applicable to the thick wafer and achieving the technical effect of having the operating voltage range of the exposure machine adjusted to accommodate the voltage values of the thick and thin wafers.

(3) In the embodiments of the application, the location of the flatten edge of the thick wafer resting on the table is detected, and the location of the flatten edge of the thin wafer resting on the table is adjusted according to the resting location of the flatten edge of the thick wafer, or both the flatten edges of the thick and thin wafers are adjusted repeatedly, thereby addressing the technical problem in the prior art that the flatten edges of the thick and thin wafers can not be detected by using the same exposure machine and achieving the technical effects of ensuring compatibility in pre-alignment between the thick and thin wafers on the table and normally detecting the flatten edges of the thick and thin wafers.

(4) In the embodiments of the application, the cylinder stroke baffle of the table in the Y direction is removed, and the distance between the preset wheels in the Y direction is adjusted, thereby addressing the technical problem in the prior art that the positioning length in the Y direction can not be adjusted and achieving the technical effect that the distance in the Y direction can accommodate the operation of both the thick and thin wafers.

(5) In the embodiments of the application, the thick and thin wafers are manufactured respectively on the improved table for testing to ensure that the exposure machine adjusted in the solution according to the embodiment of the application can pre-align the thick wafer and also pre-align the thin wafer using the same imprint parameters, thus achieving the technical effect of direct stable operation of 280 μm thin wafer products without any modification after the thick wafer is produced.

### BRIEF DESCRIPTION OF THE DRAWINGS

FIG. 1 is a flow chart of a debugging method for pre-alignment according to an embodiment of the application;

FIG. 2 is a schematic diagram of comparison between thin and thick wafers according to an embodiment of the application; and

FIG. 3 is a diagram of comparison between an unadjusted machine and a machine adjusted by using a solution according to an embodiment of the application.

### DETAILED DESCRIPTION OF THE EMBODIMENTS

Embodiments of the application provide a debugging method for pre-alignment so as to address the technical problem in the prior art that thin and thick wafers can not be operated on the same exposure machine.

In order to address the foregoing problem, a general idea of a technical solution according to the embodiments of the application is as follows:

A debugging method for pre-alignment is provided, and the method includes:

obtaining a preset voltage value, where the preset voltage value is an average voltage value of a first voltage value corresponding to a thin wafer placed on a table of the electronic device and a second voltage value corresponding to a thick wafer placed on the table of the electronic device;

detecting and acquiring a first operation, and correcting a third voltage value of the electronic device according to the preset voltage value in response to the first operation so that a voltage difference between the third voltage value and the preset voltage value lies in a preset voltage range;

detecting location of a flatten edge of the thick wafer on the table of the electronic device to obtain first location information, and detecting location of a flatten edge of the thin wafer on the table of the electronic device to obtain second location information; and

detecting and acquiring a second operation, and correcting the second location information according to the first location information in response to the second operation so that an angle difference between the corrected second location information and the first location information lies in a preset angle range.

As can be apparent, in the embodiment of the application, the voltage value of the machine is adjusted according to the average value of the voltages of the thick and thin wafers separately operated on the machine so that the voltage value of the machine can accommodate both the thick and thin wafers for operation, and the location of the flatten edge of the thin wafer on the machine is adjusted according to the location of the flatten edge of the thick wafer on the machine so that the positioning system of the machine can position both the flatten edges of the thick and thin wafers, thereby addressing the technical problem in the prior art that the thin wafer can not be operated on the machine with which the thick wafer is manufactured and achieving the technical effect of operating the thick and thin wafers compatibly.

In order to better understand the foregoing technical solution, the foregoing technical solution will be described below in details with reference to the drawings and particular embodiments.

An embodiment of the application provides a debugging method for pre-alignment, which is applicable to an exposure machine in a process of manufacturing thin and thick wafers from silicon wafers of semiconductor materials, and in the embodiment of the application, a Nikon Stepper machine and NSR1755G7A silicon wafers are adopted by way of an example. In a particular implementation, in order to perform the steps of the method according to the application, firstly the debugging process of the exposure machine according to the application is performed by using manufactured thin and thick wafers.

In the case that a flatten edge of a 625-675 μm thick wafer can be normally located but a flatten edge of a 280 μm thin wafer can not be detected by pre-alignment on an OF table of the exposure machine:

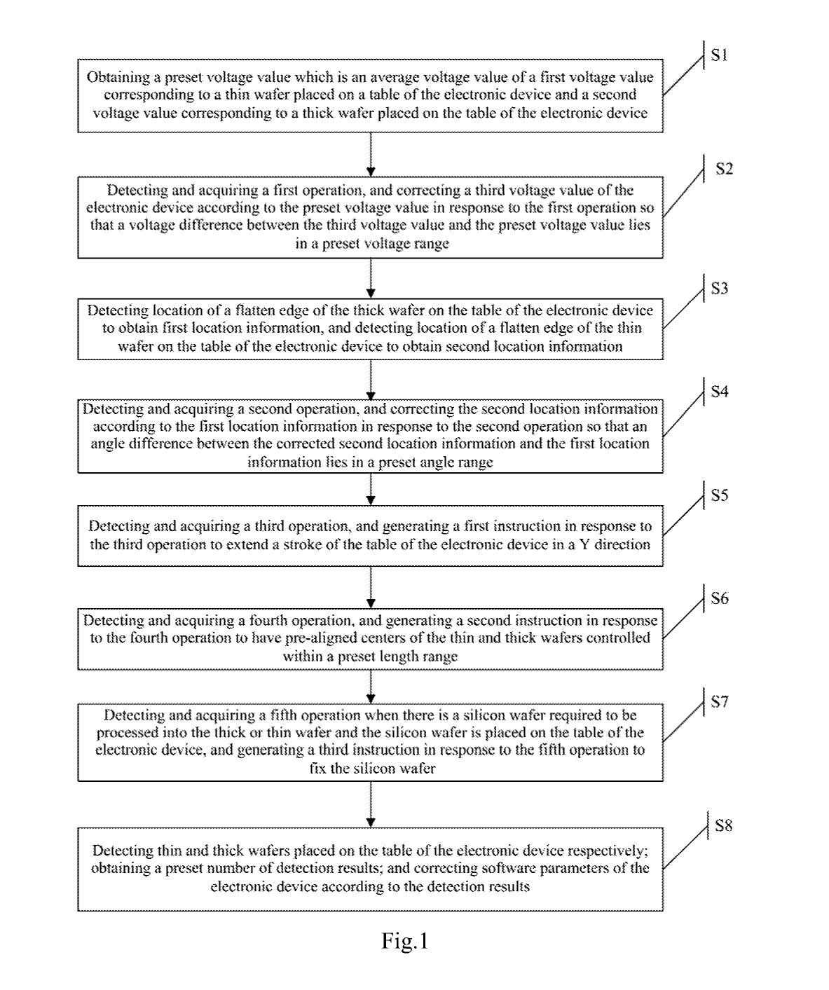

As illustrated in FIG. 1, a debugging method for pre-alignment according to an embodiment of the application particularly includes the following steps:

Step S1: obtaining a preset voltage value which is an average voltage value of a first voltage value corresponding to a thin wafer placed on a table of the electronic device and a second voltage value corresponding to a thick wafer placed on the table of the electronic device.

Step S2: detecting and acquiring a first operation, and correcting a third voltage value of the electronic device according to the preset voltage value in response to the first operation so that a voltage difference between the third voltage value and the preset voltage value lies in a preset voltage range.

In a particular implementation, the steps S1 and S2 are performed for the purpose of optimizing the voltage range of the table. The thick wafer is placed on the exposure machine, and the voltage across points OFADJ+ and OFADJ− is detected and recorded; and the thin wafer is placed on the OF table, waveforms at test points are monitored using an oscillograph, A/B/C/D peak voltages are recorded, and the voltage across points OFADJ+ and OFADJ− of the thin wafer at this time is calculated. The previously recorded voltage value across points OFADJ+ and OFADJ− of the thick wafer and the newly calculated voltage value across points OFADJ+ and OFADJ− of the thin wafer are added up and then averaged; and the calculated average voltage value corresponds to test points TP15 (OFADJ+) and TP16 (OFADJ−), and VR9 (OFADJ+) and VR12 (OFADJ−) of the exposure machine are corrected to thereby be equal to the calculated average voltage with controlling an error to be no more than ±20 mV.

As can be apparent, in the embodiment of the application, the voltage values required for the exposure machine in manufacturing the finished thick and thin wafers are detected and then averaged, and the voltage value of the exposure machine is adjusted using the average voltage value, thereby addressing the technical problem in the prior art that voltage test points of the exposure machine can only be directly applicable to the thick wafer and achieving the technical effect of having the operating voltage range of the exposure machine adjusted to accommodate the voltage values of the thick and thin wafers.

Step S3: detecting location of a flatten edge of the thick wafer on the table of the electronic device to obtain first location information, and detecting location of a flatten edge of the thin wafer on the table of the electronic device to obtain second location information.

Step S4: detecting and acquiring a second operation, and correcting the second location information according to the first location information in response to the second operation so that an angle difference between the corrected second location information and the first location information lies in a preset angle range.

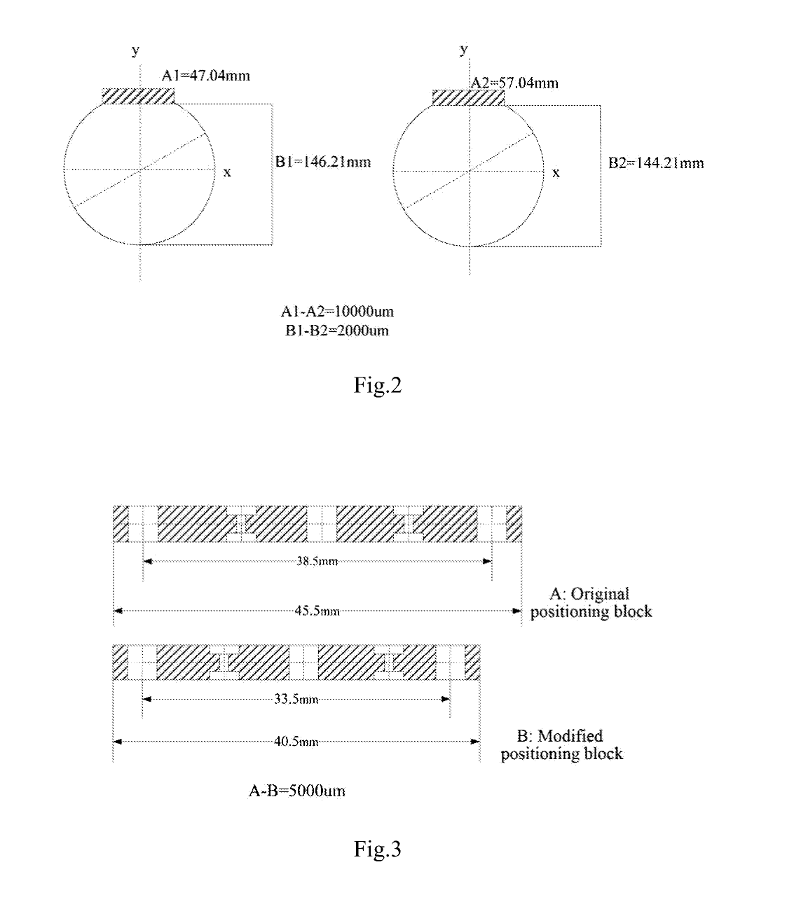

In a particular implementation, as illustrated in FIG. 2, the thick and thin wafers can not be positioned on the same machine in the prior art due to the different specifications of the two wafers. The steps S3 and S4 are performed for the purpose of correcting the locations where the flatten edges of the thick and thin wafers rest on the table. In the case that the flatten edge of the thick wafer can be normally located, the location of the flatten edge of the thick wafer resting on the table is taken as a reference, and after the thin wafer is placed on the table, it is determined that the thin wafer can rest normally and have its flatten edge detected within two rounds of rotation; and if the X direction of the thin wafer is not parallel, then the A-23 PCB S3 DIP switch of the exposure machine is revised until being qualified; and if an optical edge-removing machine is adopted, then the resting location after removal of the edge will be further observed, and also the A-22 PCB S8 DIP switch of the exposure machine will be revised until being qualified. The thick and thin wafers can be placed respectively and the locations where the flatten edges rest will be observed in turn to thereby ensure the angle difference between the locations where the two types of wafers rest to be below 20 degrees.

As can be apparent, in the embodiment of the application, the location of the flatten edge of the thick wafer resting on the table is detected, and the location of the flatten edge of the thin wafer resting on the table is adjusted according to the resting location of the flatten edge of the thick wafer, or both the flatten edges of the thick and thin wafers are adjusted repeatedly, thereby addressing the technical problem in the prior art that the flatten edges of the thick and thin wafers can not be detected by using the same exposure machine and achieving the technical effects of ensuring compatibility in pre-alignment between the thick and thin wafers on the table and normally detecting the flatten edges of the thick and thin wafers.

After the step S4, the method further includes:

Step S5: detecting and acquiring a third operation, and generating a first instruction in response to the third operation to extend a stroke of the table of the electronic device in a Y direction, wherein the third operation is an operation to remove a cylinder stroke baffle of the table of the electronic device in the Y direction.

In a particular implementation, in this step, a cylinder stroke baffle of a bracket of the table of the exposure machine in the Y direction is removed, and after the exposure machine responds to this operation, the traveling stroke in the Y direction can be extended by approximately 2100 μm, and both the center points of the thin and thick wafers are closer to a wafer holder with a difference below 300 μm.

After the step S5, the method further includes:

Step S6: detecting and acquiring a fourth operation, and generating a second instruction in response to the fourth operation to have pre-aligned centers of the thin and thick wafers controlled within a preset length range, wherein the fourth operation is an operation to adjust a distance between preset wheels of the table of the electronic device in the Y direction.

In a particular implementation, the base of the machine is reengineered, and as illustrated in FIG. 3, the distance between flatten edges of thin wafers is 47,000 μm, the distance between centers of two preset wheels of the positioning block of the table is 38,000 μm, and the distance between edges is 45,500 μm, so the positioning center of the flatten edge in the X direction is within 750 μm, which is difficult to achieve in hardware positioning, and the distance between the preset wheels of the positioning block in the Y direction is modified, and for the modified positioning block, the distance between the centers of the two wheels is 34,000 μm, and the distance between the edges is 40,500 μm, both of which have been reduced by 5000 μm; and the positioning center of the flatten edge in the X direction is increased to 3250 μm, and the modification can have the pre-aligned centers of the thin and thick wafers controlled within 100 μm, thereby coming into an automatic search range.

As can be apparent, in the embodiment of the application, the cylinder stroke baffle of the table in the Y direction is removed, and the distance between the preset wheels in the Y direction is adjusted, thereby addressing the technical problem in the prior art that the positioning length in the Y direction can not be adjusted and achieving the technical effect that the distance in the Y direction can accommodate the operation of both the thick and thin wafers.

After the step S6, the method further includes:

Step S7: detecting and acquiring a fifth operation when there is a silicon wafer required to be processed into the thick or thin wafer and the silicon wafer is placed on the table of the electronic device, and generating a third instruction in response to the fifth operation to fix the silicon wafer, wherein the fifth operation is an operation to fix the silicon wafer respectively in three directions Y, X and T of the table of the electronic device.

In a particular embodiment, this step is a process of optimizing the positioning of the silicon wafer. This is performed based upon the six foregoing steps, where a silicon wafer is placed on the table of the exposure machine, when the wafer is received respectively from a load slider ARM after a series of operations including flatten edge alignment and other operations are performed, and it is preferable that the silicon wafer does no shake with a gas flow after knocking by a hammer for compressing air of the component with the flatten edge; and the hammer and the X and Y positioning blocks are required to travel in the three direction at the same time during positioning, where respective throttles of the gas holder (WFLOW), the wafer holder and the hammer can be adjusted for synchronization.

After the step S7, the method further includes step S8:

detecting thin and thick wafers placed on the table of the electronic device respectively;

obtaining a preset number of detection results; and

correcting software parameters of the electronic device according to the detection results.

In a particular implementation, this step is performed to correct the software parameters of the entire exposure machine. The thick wafer is made of the 625-675 μm silicon wafer, and then a dedicated wafer is pre-aligned to make the 280 μm thin wafer. This is performed for 60 times as a reference, and the average value is required to be below 5 μm and 3 Sigam is required to be below 10 μm. In particular steps, firstly the 176USER.REG1 menu is selected, the 280 μm thin wafer coated with light resistances is exposed and developed at the first layer, and then the 176USER.EGA menu is selected, and the stability of pre-alignment is measured in the WLRPTW option. This is performed for 60 times as a reference, and the 3 Sigma value is highly regarded, and concurrently the 675 μm thick matching wafer is also operated. Their data is compared with each other, and the offset value is corrected in the Wafer Pre-Alignment Position option until the 3 Sigma data of the two types of wafers is below 10 μm.

As can be apparent, in the embodiment of the application, the thick and thin wafers are manufactured respectively on the improved table for testing to ensure that the exposure machine adjusted in the solution according to the embodiment of the application can pre-align the thick wafer and also pre-align the thin wafer using the same imprint parameters, thus achieving the technical effect of direct stable operation of 280 μm thin wafer products without any modification after the thick wafer is produced.

One or more technical solutions according to the embodiments of the application have at least the following technical effects or advantages:

(1) In the embodiments of the application, the voltage value of the machine is adjusted according to the average value of the voltages of the thick and thin wafers separately operated on the machine so that the voltage value of the machine can accommodate both the thick and thin wafers for operation, and the location of the flatten edge of the thin wafer on the machine is adjusted according to the location of the flatten edge of the thick wafer on the machine so that the positioning system of the machine can position both the flatten edges of the thick and thin wafers, thereby addressing the technical problem in the prior art that the thin wafer can not be operated on the machine with which the thick wafer is manufactured and achieving the technical effect of operating the thick and thin wafers compatibly.

(2) In the embodiments of the application, the voltage values required for the exposure machine in manufacturing the finished thick and thin wafers are detected and then averaged, and the voltage value of the exposure machine is adjusted using the average voltage value, thereby addressing the technical problem in the prior art that voltage test points of the exposure machine can only be directly applicable to the thick wafer and achieving the technical effect of having the operating voltage range of the exposure machine adjusted to accommodate the voltage values of the thick and thin wafers.

(3) In the embodiments of the application, the location of the flatten edge of the thick wafer resting on the table is detected, and the location of the flatten edge of the thin wafer resting on the table is adjusted according to the resting location of the flatten edge of the thick wafer, or both the flatten edges of the thick and thin wafers are adjusted repeatedly, thereby addressing the technical problem in the prior art that the flatten edges of the thick and thin wafers can not be detected by using the same exposure machine and achieving the technical effects of ensuring compatibility in pre-alignment between the thick and thin wafers on the table and normally detecting the flatten edges of the thick and thin wafers.

(4) In the embodiments of the application, the cylinder stroke baffle of the table in the Y direction is removed, and the distance between the preset wheels in the Y direction is adjusted, thereby addressing the technical problem in the prior art that the positioning length in the Y direction can not be adjusted and achieving the technical effect that the distance in the Y direction can accommodate the operation of both the thick and thin wafers.

(5) In the embodiments of the application, the thick and thin wafers are manufactured respectively on the improved table for testing to ensure that the exposure machine adjusted in the solution according to the embodiment of the application can pre-align the thick wafer and also pre-align the thin wafer using the same imprint parameters, thus achieving the technical effect of direct stable operation of 280 μm thin wafer products without any modification after the thick wafer is produced.

Evidently those skilled in the art can make various modifications and variations to the invention without departing from the spirit and scope of the invention. Thus the invention is also intended to encompass these modifications and variations thereto so long as these modifications and variations come into the scope of the claims appended to the invention and their equivalents.

1. A debugging method for pre-alignment, which is applicable to an electronic device and comprises:
obtaining a preset voltage value which is an average voltage value of a first voltage value corresponding to a thin wafer placed on a table of the electronic device and a second voltage value corresponding to a thick wafer placed on the table of the electronic device;
detecting and acquiring a first operation, and correcting a third voltage value of the electronic device according to the preset voltage value in response to the first operation so that a voltage difference between the third voltage value and the preset voltage value lies in a preset voltage range;
detecting location of a flatten edge of the thick wafer on the table of the electronic device to obtain first location information, and detecting location of a flatten edge of the thin wafer on the table of the electronic device to obtain second location information; and
detecting and acquiring a second operation, and correcting the second location information according to the first location information in response to the second operation so that an angle difference between the corrected second location information and the first location information lies in a preset angle range.

2. The method according to claim 1, wherein after detecting and acquiring the second operation and correcting the second location information according to the first location information in response to the second operation, the method further comprises:
detecting and acquiring a third operation, and generating a first instruction in response to the third operation to extend a stroke of the table of the electronic device in a Y direction, wherein the third operation is an operation to remove a cylinder stroke baffle of the table of the electronic device in the Y direction.

3. The method according to claim 2, wherein after detecting and acquiring the third operation and generating the first instruction in response to the third operation to extend the stroke of the table of the electronic device in the Y direction, the method further comprises:
detecting and acquiring a fourth operation, and generating a second instruction in response to the fourth operation to have pre-aligned centers of the thin and thick wafers controlled within a preset length range, wherein the fourth operation is an operation to adjust a distance between preset wheels of the table of the electronic device in the Y direction.

4. The method according to claim 3, wherein after detecting and acquiring the fourth operation and generating the second instruction in response to the fourth operation to have the pre-aligned centers of the thin and thick wafers controlled within the preset length range, the method further comprises:
detecting and acquiring a fifth operation when there is a silicon wafer required to be processed into the thick or thin wafer and the silicon wafer is placed on the table of the electronic device, and generating a third instruction in response to the fifth operation to fix the silicon wafer, wherein the fifth operation is an operation to fix the silicon wafer respectively in three directions Y, X and T of the table of the electronic device.

5. The method according to claim 4, wherein after detecting and acquiring the fifth operation and generating the third instruction in response to the fifth operation to fix the silicon wafer, the method further comprises:
detecting thin and thick wafers placed on the table of the electronic device respectively;
obtaining a preset number of detection results; and
correcting software parameters of the electronic device according to the detection results.
